(19) United States
(12) Patent Application Publication
(10) Pub. No.: US 2017/0204526 A1
(43) Pub. Date: Jul. 20, 2017

(54) ELECTRODE, ELECTROCHEMICAL CELL, ELECTROCHEMICAL APPARATUS AND METHOD FOR MANUFACTURING ELECTRODE

(71) Applicant: Kabushiki Kaisha Toshiba, Minato-ku (JP)

(72) Inventors: Norihiro Yoshinaga, Kawasaki (JP); Shigeru Matake, Yokohama (JP); Wu Mei, Yokohama (JP); Atsuko Iida, Yokohama (JP)

(73) Assignee: Kabushiki Kaisha Toshiba, Minato-ku (JP)

(21) Appl. No.: 15/259,414

(22) Filed: Sep. 8, 2016

(30) Foreign Application Priority Data
Jan. 19, 2016 (JP) 2016-008177

(51) Int. Cl. C25B 11/04; C25B 11/03; C23C 14/34

(52) U.S. Cl. CPC C25B 11/0484; C23C 14/34; C25B 11/0494; C25B 11/035

(57) ABSTRACT

An electrode of an embodiment includes a substrate, an intermediate layer provided on the substrate, and a catalyst layer provided on the intermediate layer. The intermediate layer is a mixture that includes two or more substances among a compound, and single element of noble metal or an alloy including noble metal. In a composition ratio of the mixture, a composition ratio of the intermediate layer in the vicinity of an interface between the substrate and the intermediate layer is different from a composition ratio of the intermediate layer in the vicinity of an interface between the catalyst layer and the intermediate layer.

### CROSS-REFERENCE TO RELATED APPLICATION

This application is based upon and claims the benefit of priority from Japanese Patent Application No. 2016-008177, filed on Jan. 19, 2016; the entire contents of which are incorporated herein by reference.

### FIELD

Embodiments described herein relate to an electrode, an electrochemical cell, an electrochemical apparatus and a method for manufacturing the electrode.

### BACKGROUND

A dimensionally stable electrode (DSE) including a titanium substrate coated with noble metal oxide has been conventionally adopted as an electrode catalyst used for water electrolysis, brine electrolysis, or the like. It has been reported that electrode degradation is caused by wear and delamination of a catalyst from the titanium substrate. In particular, the delamination is caused by mismatching of the titanium substrate and the noble metal oxide as a catalyst. It has been known that, in order to solve this problem, an intermediate layer including tantalum oxide or the like of which a thermal expansion coefficient is intermediate between the noble metal oxide and the titanium is provided to improve durability. However, higher activation and simplification of processes or the like have been demanded.

### BRIEF DESCRIPTION OF THE DRAWINGS

FIG. 1 is an electrode according to a first embodiment;

FIG. 2 is an electrochemical cell according to a second embodiment; and

FIG. 3 is an electrochemical apparatus using the electrochemical cell according to the second embodiment.

### DETAILED DESCRIPTION

An electrode of an embodiment includes a substrate, an intermediate layer provided on the substrate, and a catalyst layer provided on the intermediate layer. The intermediate layer is a mixture that includes two or more substances among a compound, and single element of noble metal or an alloy including noble metal. In a composition ratio of the mixture, a composition ratio of the intermediate layer in the vicinity of an interface between the substrate and the intermediate layer is different from a composition ratio of the intermediate layer in the vicinity of an interface between the catalyst layer and the intermediate layer.

Hereinbelow, an electrode, an electrochemical cell, and an electrochemical apparatus according to embodiments will be described with reference to the drawings.

### First Embodiment

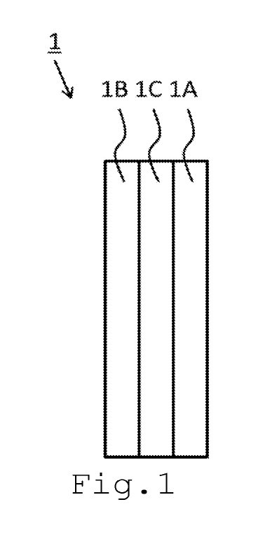

FIG. 1 is an electrode according to a first embodiment.

The electrode 1 includes a substrate 1A, a catalyst layer 1B, and an intermediate layer 1C interposed therebetween. Hereinbelow, the substrate 1A, the catalyst layer 1B, and the intermediate layer 1C will be described in detail.

[Substrate]

The substrate 1A of the electrode 1 requires porosity and conductivity. When used as the substrate 1A of an anode, titanium (Ti) is generally adopted for the purpose of securing durability. As a Ti substrate, expand metal and a mesh prepared by performing etching may be used, and non-woven fabric, metal foam, sintered metal and the like may also be used.

Regarding a material of the substrate other than those described above, examples thereof include a metal element such as tantalum (Ta) and nickel (Ni) or an alloy thereof, or stainless steel (SUS). These materials are properly selected and used in accordance with a reaction potential of an anode in the electrochemical cell 10 described later. A reference for selecting a material of the substrate 1A can be confirmed by a potential-pH diagram or the like. For example, in a case of an electrode substrate of an anode used for production of sodium hydroxide, Ni and SUS are eluted therefrom, and therefore cannot be used. Consequently, Ti is preferably used.

[Catalyst Layer]

The catalyst layer 1B is formed on one surface or both surfaces of the substrate 1A of the electrode 1. A catalyst material for forming the catalyst layer 1B is properly selected and used in accordance with a reaction in the electrode 1. The catalyst layer 1B preferably includes a metal oxide layer or/and noble metal.

As a material for forming a catalyst layer of an anode for brine electrolysis or for generating oxygen, iridium oxide is mainly used. That is because iridium oxide has excellent water electrolysis performance and durability.

In addition, noble metal catalysts such as platinum (Pt) and palladium (Pd), lead oxide, ruthenium oxide, iridium composite oxide, ruthenium composite oxide, and other oxide catalysts can be used.

As composite metal constituting the oxides, at least one kind of metal among Ti, niobium (Nb), vanadium (V), chromium (Cr), manganese (Mn), cobalt (Co), zinc (Zn), zirconium (Zr), molybdenum (Mo), Ta, tungsten (W), thallium (Tl), ruthenium (Ru), and iridium (Ir) is exemplified.

As a material for forming a catalyst layer of an anode used for a fuel cell with which electrolytic hydrogen is generated and hydrogen oxidation and methanol oxidation are performed, a platinum-group catalyst (including Pt, PtCo, PtFe, PtNi, PtPd, PtIr, PtRu, and PtSn) is preferably used.

From the viewpoint of durability and large surface areas of the catalyst layers theirselves, these catalyst layers 1B preferably include an aggregate layer and a gap layer. The aggregate layer includes metal oxide or/and noble metal included in the catalyst layer 1B, and the gap layer includes a hollow region. It is preferable to include a structure in which the aggregate layers and the gap layers are sequentially stacked. As a method for preparing the catalyst layer 1B, a method is exemplified. In the method, a mixed layer including a catalyst material and a pore forming material, and a pore forming material layer are sequentially sputtered. Then, the pore forming material in the obtained mixed layer and the pore forming material layer are dissolved and removed, thereby forming the catalyst layer 1B which has a laminated structure including the aggregate layers and the gap layers. At that time, the catalyst layer 1B includes a plurality of laminated catalyst aggregate layers having an average thickness of 4 nm to 50 nm, and gap layers of 10 nm to 100 nm interposed between adjacent catalyst aggregate layers. These catalyst layers preferably have a porous structure. The porous structure means a structure including a number of pores present in the catalyst layers. There is no particular limitation for a shape of the pores. That is because the pores in the catalyst layers facilitate smooth transportation of substances to improve, for example, water electrolysis properties.

The aggregate layers in the catalyst layer 1B are partially connected, and substantially all the catalyst layers are restrained by the intermediate layers and the substrate. Consequently, a remarkably stable structure is obtained.

The catalyst layer 1B of the embodiment can be used for both an anode electrode and a cathode electrode.

[Intermediate Layer]

The intermediate layer 1C is a mixture including two or more of a compound, and single element of noble metal or an alloy including noble metal, of which thermal expansion coefficients are different from each other. The intermediate layer 1C is disposed between the substrate 1A and the catalyst layer 1B. A composition ratio of the mixture of the intermediate layer 1C in the vicinity of an interface between the intermediate layer and the substrate is different from that in the vicinity of an interface between the intermediate layer and the catalyst layer.

The interface refers to a border portion where the intermediate layer 1C is in contact with the substrate 1A or the catalyst layer 1B. The interface between the intermediate layer 1C and the catalyst layer 1B is preferably defined as follows. The electrode 1 which has a region including the catalyst layer is magnified and observed by a transmission electron microscope (TEM), an end portion of the catalyst layer is identified from a structural feature of the catalyst layer 1B described above, and contact portions between the identified end portion and the intermediate layer are connected by a line to obtain a side. The interface is defined as the side. In order to identify the intermediate layer 1C and the catalyst layer 1B, it is preferable to perform an analysis by a TEM equipped with an energy dispersive X-ray spectroscope (EDX). The interface between the intermediate layer 1C and the substrate 1A is preferably identified based on crystallinity observed by the TEM and an elemental analysis using the EDX in a similar manner. A distance between the two interfaces thus obtained is preferably defined as a thickness of the intermediate layer 1C. The thickness of the catalyst layer 1B is also obtained from the TEM analysis.

The compound means a substance from which two or more kinds of elemental substances can be obtained through a chemical reaction, and herein refers to iridium oxide, ruthenium oxide, and the like.

The alloy means a substance including a plurality of metal elements or a metal element and a non-metal element, and herein refers to PtFe, PtNi, and the like.

The noble metal herein refers to gold (Au), silver (Ag), Pt, Pd, and the like.

The composition ratio of a mixture means, for example, when the intermediate layer includes a mixture of iridium oxide and Pt, a ratio between the number of iridium oxide molecules and the number of Pt atoms in a region.

The substrate 1A and the catalyst layer 1B have a first thermal expansion coefficient (λ1) and a second thermal expansion coefficient (λ2), respectively. In general, the first thermal expansion coefficient and the second thermal expansion coefficient are different from each other. Here, in the intermediate layer 1C, the vicinity of the interface with the substrate 1A is adjusted to have a thermal expansion coefficient similar to the first thermal expansion coefficient of the substrate 1A.

In addition, in the intermediate layer 1C, the vicinity of the interface with the catalyst layer 1B is adjusted to have a thermal expansion coefficient similar to the second thermal expansion coefficient of the catalyst layer 1B. By doing so, it is possible to successively change a thermal expansion coefficient of the electrode 1 in a thickness direction, to suppress delamination of the catalyst layer 1B from the substrate 1A caused by thermal deformation or the like, and to realize the electrode 1 having higher durability. The thermal expansion coefficient of each layer is obtained by an X-ray diffraction method.

Specifically, in a case where examples of the substrate 1A include aluminum (Al), Ta, niobium (Nb), Ti, hafnium (Hf), Zr, Zn, W, bismuth (Bi), and antimony (Sb), and examples of the catalyst layer 1B includes iridium oxide (IrO₂), ruthenium oxide and a composite oxide including these oxides, for example, the mixture included in the intermediate layer 1C preferably includes at least one kind from each of the following groups A and B. A valve metal oxide is an oxide of metal such as Al, Ti, and chromium (Cr), Nb, W, Molybdenum (Mo), Vanadium (V) Bi, Zr Silicon (Si), Zn, Sb, or an oxide of an alloy of these metals.

Group A: iridium oxide, ruthenium oxide, gold

Group B: valve metal oxide, platinum

In that case, in comparison between an amount B1 of substances belonging to the group B in the vicinity of the interface with the substrate 1A and an amount B2 of substances belonging to the group B in the vicinity of the interface with the catalyst layer 1B, the expression B1>B2 is preferably satisfied. The reason therefor is as follows. For example, when the substrate 1A is Ti or the like, since the thermal expansion coefficient of Ti is similar to the thermal expansion coefficient of Pt or the like in the group B, an increase in the amount of substances belonging to the group B in the vicinity of the interface with the substrate results in improvement of durability against thermal deformation of the substrate 1A and the intermediate layer 1C. Here, the vicinity of the interface with the substrate 1A means a region in the intermediate layer 1C located within a thickness of 0.1×L (L denotes a thickness of the intermediate layer 1C) to the catalyst layer 1B from the interface between the substrate 1A and the intermediate layer 1C. In addition, the vicinity of the interface with the catalyst layer 1B means a region in the intermediate layer 1C located within a thickness of 0.1×L (L denotes a thickness of the intermediate layer 1C) to the substrate 1A from the interface between the catalyst layer 1B and the intermediate layer 1C. The amounts of substances B1 and B2 each mean an average value obtained from three samples randomly collected in each of the regions. Consequently, an effect of higher durability can be further secured.

Furthermore, an amount (on a molar basis) of substances belonging to the group A present in a region in the intermediate layer 1C located within a thickness of 0.1×L to the catalyst layer 1B from the interface between the substrate 1A and the intermediate layer 1C is preferably greater than 0% and less than or equal to 10%. The amount of substances belonging to the group B having a thermal expansion coefficient similar to that of the substrate 1A increases, and thereby the effect of higher durability can be further secured. An amount (on a molar basis) of substances belonging to the group A present in a region in the intermediate layer 1C located within a thickness of 0.1×L to the catalyst layer 1B from the interface between the substrate 1A and the intermediate layer 1C is more preferably from 1% to 10%, and still more preferably from 3% to 8%.

In the vicinity of the interface with the catalyst layer 1B in the intermediate layer 1C, it is preferable to increase the amount of substances belonging to the group A in substitution for a small amount of substances belonging to the group B. The reason therefor is as follows. Since IrO₂ or the like is mainly used for the catalyst layer of an anode, durability against thermal deformation of the catalyst layer 1B and the intermediate layer 1C can be improved by selecting a substance belonging to the group A having a similar thermal expansion coefficient.

The thickness of the intermediate layer 1C is preferably less than 500 nm. The thickness of the intermediate layer 1C is more preferably less than or equal to 200 nm. The reason therefor is as follows. When a distance between the substrate 1A and the catalyst layer 1B is long in a chemical reaction in the electrode, resistance is increased to exert an inhibitory effect on conductivity of electrons. Therefore, it is preferable to make the distance between the substrate 1A and the catalyst layer 1B short.

The thickness of the intermediate layer 1C is preferably greater than or equal to 4 nm. When the thickness is less than 4 nm, uniformity in the film thickness is deteriorated, there occur portions where the catalyst layer 1B is directly supported on the substrate, and thereby durability is deteriorated. In addition, there is another reason therefor. In a case where a catalyst layer 1B is combined which has a laminated structure including catalyst aggregate layers and gap layers, a reaction proceeds also in the vicinity of the intermediate layer unlike a single layer catalyst such as DSE, and therefore, degradation may easily occur during electrolysis when the thickness of the intermediate layer 1C itself is small. In consideration of the above, the thickness of the intermediate layer 1C is preferably from 4 nm to 200 nm, or from 4 nm to 100 nm.

The intermediate layer 1C is prepared by using sputtering described later. By changing an amount of a compound or the like used for the sputtering or an output of the sputtering, the intermediate layer 1C can be prepared with the high degree of freedom.

Composition distribution of the intermediate layer 1C can be measured, for example, by depth analysis with XPS (X-ray Photoelectron Spectroscopy) performing Ar etching and nano EDX using cross-sectional TEM.

[Method for Manufacturing Electrode]

A method for manufacturing the electrode 1 will be described below.

First, in order to form the intermediate layer 1C on the substrate 1A, a plurality of material of the intermediate layer is used as a target. Sputtering is performed simultaneously or alternately while changing a sputtering rate for each target, thereby forming the intermediate layer 1C.

At that time, metal oxide and the like can be generated by changing a gas atmosphere in a chamber used for the sputtering, and an output of the sputtering, and thereby composition of the intermediate layer can be freely changed.

After the intermediate layer 1C is formed, a mixed layer including a catalyst material and a pore forming material, and a pore forming material layer are sequentially formed thereon by performing sputtering. The mixed layer including a catalyst material and a pore forming material is used in order for the catalyst layer to have a porous structure. The pore forming material layer is used for preparing a gap layer in the catalyst layer.

By dissolving and removing the pore forming material in the obtained mixed layer and the pore forming material layer with acid, it is possible to manufacture the electrode 1 including the catalyst layer 1B and the intermediate layer 1C, the catalyst layer 1B having a laminated structure including the catalyst aggregate layers with a porous structure and the gap layers.

### Second Embodiment

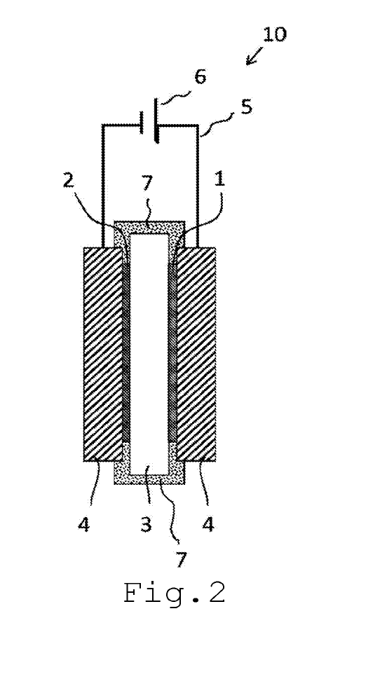

FIG. 2 is an electrochemical cell 10 according to a second embodiment.

The electrochemical cell 10 includes an electrode 1, an electrode 2, and an electrolyte membrane 3 interposed therebetween. The electrodes 1 and 2 are each equipped with a current collector plate 4, and each current collector plate 4 is connected to a direct current power supply 6 by an external circuit 5. The power supply 6 applies a voltage between the electrodes 1 and 2, and thereby a chemical reaction proceeds.

[Anode]

As the electrode 1 on an anode side, the above-described electrode according to the first embodiment is used.

The anode electrode 1 is a member which serves as an electrode of the electrochemical cell 10, plays a role of a support for a catalyst, and besides, simultaneously plays a role of a diffusion path of a substance to be reacted such as gas, and roles of a current collector and a feed conductor.

The electrode 1 having the above configuration can be suitably used as an electrode for soda electrolysis or water splitting. However, use of the electrode 1 is not limited thereto, and the electrode 1 can be used as a general electrode.

The anode electrode 1 has a porous structure. In other words, the anode electrode 1 has a plurality of through pores.

A conductive electrode substrate in the anode electrode 1 having the above-described configuration can be manufactured, for example, by wet etching, expansion processing, and punching processing. In addition, the conductive electrode substrate can be manufactured also by processing using photo-etching, laser, or precise cutting. Furthermore, non-woven fabric of fibers, a mesh, metal foam or the like can be used.

[Fastening Plate]

As a fastening plate 7, stainless steel and aluminum are preferable since it is important that the fastening plate 7 does not curve when a cell is fastened thereon.

[Cathode]

The electrode 2 of a cathode opposed to the anode may be configured with the same electrode substrate as that of the first embodiment and a catalyst layer formed on one surface of the substrate, and may be configured with the electrode substrate itself.

Examples of a material which constitutes the electrode substrate for supporting the catalyst layer of the cathode electrode 2 includes metal materials such as Ta, Ti, SUS, and Ni, an alloy thereof, carbon, or a gas diffusion layer (GDL) including carbon. These materials are properly selected and used in accordance with a reaction potential of the cathode. As an oxygen redox reaction catalyst used for a fuel cell or an oxygen-reducing device, a platinum group-based noble metal catalyst (also including Pt, PtCo, PtFe, PtNi, PtPd, PtIr, PtRu, and PtSn) is more preferable. However, other metal catalysts, nitrogen-substituted carbon catalysts, oxide catalysts and the like can also be used.

In addition, as a cathode for brine electrolysis and a cathode for generating oxygen, Ag, Pd, Pt and the like are preferable. In addition, other metal catalysts, nitrogen-substituted carbon catalysts, oxide catalysts, carbon and the like can also be used.

The catalyst layer of the cathode electrode 2 can also be prepared on the electrode substrate by sputtering, as with the electrode according to the first embodiment. The catalyst layer can also be prepared by directly applying, to the electrode substrate, a suspension obtained by dispersing catalyst powder in water, alcohol, or the like. In addition to the case of applying a catalyst to the electrode substrate described above, in a case where the electrode substrate itself functions as a catalyst and has an activity to a reaction, the cathode electrode 2 can be formed by the substrate alone. Therefore, the electrode does not need the catalyst layer. As a material which constitutes the electrode substrate, a platinum group-based noble metal catalyst such as Pt is exemplified. Furthermore, the anode can be used as an elution electrode in which the electrode is worn with a reaction in accordance with use conditions of the electrochemical cell.

[Electrolyte Membrane]

As the electrolyte membrane 3, a polymer electrolyte membrane can be used. For example, a cation exchange solid polymer electrolyte membrane, specifically, a cation exchange membrane, an anion exchange membrane, or a hydrocarbon-based membrane can be used. Examples of the cation exchange membrane include Nafion (trademark) 112, 115, and 117, Flemion (trademark), Aciplex (trademark), and GORE-SELECT (trademark). As the anion exchange membrane, A201 (manufactured by Tokuyama Corporation) is exemplified.

[Electrochemical Cell]

The electrochemical cell 10 having the above-described configuration is manufactured by hot-pressing the anode electrode 1 and the cathode electrode 2 with the electrolyte membrane 3 interposed therebetween to bond the electrolyte membrane 3 and the anode electrode 1 as well as the electrolyte membrane 3 and the cathode electrode 2.

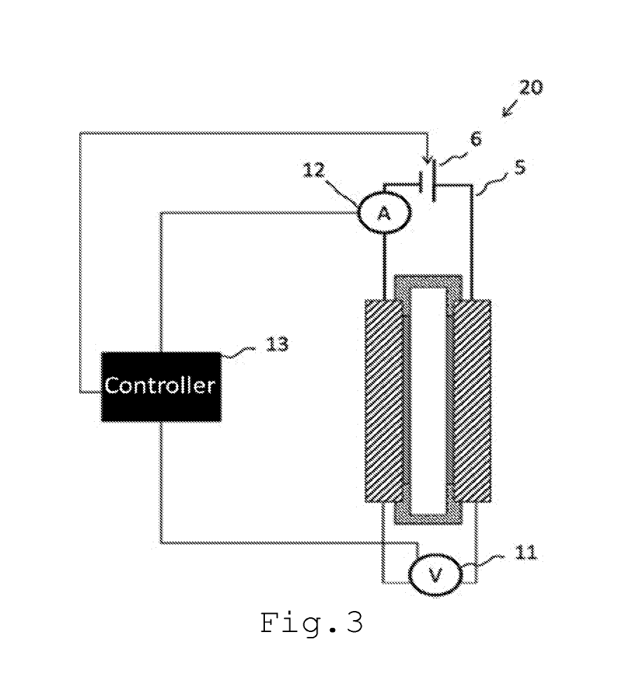

An electrochemical apparatus 20 which includes the electrochemical cell 10 is illustrated in FIG. 3. The electrochemical apparatus 20 further includes a voltage applying unit (power supply) 6, a voltage measuring unit 11, a current measuring unit 12, and a controller 13.

Both electrodes of the power supply 6 are electrically connected to the anode electrode 1 and the cathode electrode 2, respectively.

The controller 13 controls the power supply 6 so as to apply a voltage to the electrochemical cell 10. The voltage measuring unit 11 is, for example, a voltmeter, and electrically connected to the anode electrode 1 and the cathode electrode 2 so as to measure a voltage applied to the electrochemical cell 10. Information obtained from the measurement is supplied to the controller 13. The current measuring unit 12 is, for example, an ammeter, and inserted in a voltage applying circuit for the electrochemical cell 10 so as to measure a current flowing through the electrochemical cell 10. Information obtained from the measurement is supplied to the controller 13. The controller 13 controls, in accordance with a program stored in a memory included therein, an output of the power supply 6 based on the Information obtained from each measurement, thereby performing controls such as application of a voltage to the electrochemical cell 10, or change of a load. The controller 13 is not particularly limited and examples thereof include hard control using a microcomputer, or an IC such as field programmable gate arrays (FPGA), and soft control using a personal computer or the like.

In a case where an electrochemical cell 10 is used for a battery reaction, a voltage is applied to the electrochemical cell 10. In a case where an electrochemical cell 10 is used for a reaction other than a battery reaction, for example, for generating hydrogen through water electrolysis, a voltage is applied to the electrochemical cell 10.

The electrochemical apparatus 20 applies a voltage between the anode electrode 1 and the cathode electrode 2, thereby causing an electrochemical reaction to proceed.

By forming the anode electrode 1 included in the electrochemical cell 10 into the electrode according to the first embodiment, it is possible to reduce an amount of a catalyst used and to improve durability of the anode.

[Operation of Electrochemical Cell]

Next, an operation of the electrochemical cell 10 will be described. In a case of water electrolysis, when a voltage is applied from the outside, water is electrolyzed in the anode electrode 1 to cause a reaction represented by Formula (1).

2H₂→O₂+4H⁺+4e⁻ (1)

Protons (H⁺) and electrons (e⁻) generated in the reaction reach the cathode electrode 2 through the electrolyte membrane 3 and the external circuit 5, respectively. In the cathode electrode 2, hydrogen is generated according to a reaction represented by Formula (2).

2H⁺+2e⁻→H₂ (2)

Through this reaction, hydrogen and oxygen can be produced.

### EXAMPLES

### Examples 1 to 6

An electrochemical apparatus 20 including an electrochemical cell 10 illustrated in FIG. 2 is manufactured, and water electrolysis properties are evaluated using the electrochemical apparatus 20. The electrochemical apparatus 20 is illustrated in FIG. 3.

In Examples 1 to 6, a cathode electrode 2 described below is used. A mixture including 705 mg of Pt/C (manufactured by Tanaka Kikinzoku Kogyo K.K.), 5 cc of water, and 3 mL of a 5 wt % Nafion (trademark) solution is prepared. The mixture is ultrasonically dispersed for 30 minutes. A suspension obtained through the above processes is sprayed onto a sheet of carbon paper (GDL25BC manufactured by CETEK, with a thickness of 0.32 mm and an area of 235 cm²) subjected to a water repellent treatment (20 wt %), and dried. The dried carbon paper sheet is cut into a piece of 5 cm×5 cm, and the piece is used as the cathode electrode 2.

Furthermore, in Examples 1 to 6, an anode electrode 1 described below is used. As a substrate 1A, a Ti non-woven fabric substrate having a size of 5 cm×5 cm and a thickness of 0.02 cm is used. By performing sputtering of Ir, Pt, or Ta on the substrate 1A using a sputtering method in argon including 10% of oxygen, an intermediate layer 1C is formed thereon. At that time, the pressure in a chamber is 1 Pa. The intermediate layer 1C is deposited by RF sputtering. For example, in Example 1, sputtering of Pt is started at 200 W, and the output is then decreased to 0 W at a rate of 10 W/s. Regarding Ir, sputtering (RF sputtering) is started at 0 W, and the output is then increased to 200 W at a rate of 10 W/s. By doing so, concentration gradations of Pt and IrO₂ are provided in a thickness direction of the intermediate layer 1C. Since Pt has a thermal expansion coefficient similar to that of Ti, it is possible to moderately alleviate changes in the thermal expansion coefficient in the vicinity of the interface with the substrate 1A. Other detailed conditions of the intermediate layers of Examples 2 to 6 are indicated in Table 1.

TABLE 1

| | TARGET: Pt | | | TARGET: Ir | | | TARGET: Ta | | |
|---|---|---|---|---|---|---|---|---|---|
| | | | CHANGE | | | CHANGE | | | CHANGE |
| | POWER W | | RATE | POWER W | | RATE | POWER W | | RATE |
| | START | END | W/sec | START | END | W/sec | START | END | W/sec |
| Eample 1 | 200 | 0 | −10 | 0 | 200 | 10 | 0 | 0 | 0 |
| Eample 2 | 80 | 0 | −10 | 0 | 80 | 10 | 0 | 0 | 0 |
| Eample 3 | 200 | 0 | −0.5 | 0 | 200 | 0.5 | 0 | 0 | 0 |
| Eample 4 | 0 | 0 | 0 | 0 | 200 | 10 | 200 | 0 | −10 |
| Eample 5 | 0 | 0 | 0 | 0 | 80 | 10 | 80 | 0 | −10 |
| Eample 6 | 0 | 0 | 0 | 0 | 200 | 0.5 | 200 | 0 | −0.5 |
| Comparative | 200 | 0 | −0.1 | 0 | 200 | 0.1 | 0 | 0 | 0 |
| Example 1 | | | | | | | | | |
| Comparative | 50 | 0 | −10 | 0 | 50 | 10 | 0 | 0 | 0 |
| Example 2 | | | | | | | | | |
| Comparative | 200 | 200 | 0 | 0 | 0 | 0 | 0 | 0 | 0 |
| Example 3 | | | | | | | | | |
| Comparative | 0 | 0 | 0 | 200 | 200 | 0 | 0 | 0 | 0 |
| Example 4 | | | | | | | | | |
| Comparative | 0 | 0 | 0 | 0 | 0 | 0 | 0 | 0 | 0 |
| Example 5 | | | | | | | | | |
| Comparative | 0 | 0 | 0 | 0 | 0 | 0 | 0 | 0 | 0 |
| Example 6 | | | | | | | | | |
| Comparative | 0 | 200 | 10 | 200 | 0 | −10 | 0 | 0 | 0 |
| Example 7 | | | | | | | | | |

| Comparative | — | | | | |
|---|---|---|---|---|---|
| Example 8 | | | | | |
| | AVERAGE | | | | |
| | THICKNESS OF | | | | DEGRADATION |
| | INTERMEDIATE | CATALYST | INITIAL | DURABILITY | REASON OF |
| | LAYER nm | LAYER | PROPERTY | hours | CATALYST |
| Eample 1 | 10 | IrO₂ | A | 15000 | Catalyst |
| | | Laminated | | | Eluted |
| Eample 2 | 4 | IrO₂ | A | 15100 | Catalyst |
| | | Laminated | | | Eluted |
| Eample 3 | 200 | IrO₂ | A | 14800 | Catalyst |
| | | Laminated | | | Eluted |
| Eample 4 | 10 | IrO₂ | A | 15500 | Catalyst |
| | | Laminated | | | Eluted |
| Eample 5 | 4 | IrO₂ | A | 15200 | Catalyst |
| | | Laminated | | | Eluted |
| Eample 6 | 200 | IrO₂ | A | 15600 | Catalyst |
| | | Laminated | | | Eluted |
| Comparative | 1000 | IrO₂ | B | 15100 | Catalyst |
| Example 1 | | Laminated | | | Eluted |
| Comparative | 2.5 | IrO₂ | A | 3000 | Interfacial |
| Example 2 | | Laminated | | | Delamination |
| Comparative | 7 | IrO₂ | A | 4000 | Interfacial |
| Example 3 | | Laminated | | | Delamination |
| Comparative | 11 | IrO₂ | A | 3900 | Interfacial |
| Example 4 | | Laminated | | | Delamination |
| Comparative | 0 | IrO₂ | A | 2900 | Interfacial |
| Example 5 | | Laminated | | | Delamination |
| Comparative | 0 | IrO₂(DSE) | C | 18000 | Catalyst |
| Example 6 | | | | | Degradation |
| Comparative | 10 | IrO₂ | A | 2500 | Interfacial |
| Example 7 | | Laminated | | | Delamination |
| Comparative | — | IrO₂ | A | 2500 | Interfacial |
| Example 8 | | Laminated | | | Delamination |

After forming the intermediate layer 1C, a catalyst layer is formed as a catalyst layer 1B. As a catalyst aggregate layer, IrO₂ is formed. First, RF sputtering of Ni as a gap layer is performed for 300 seconds at 500 W, and then RF sputtering of each of Ni and Ir as the catalyst aggregate layer is performed for 60 seconds at 200 W. The sputtering for the gap layer and the catalyst aggregate layer is repeated 20 times, and then washing with 1 M nitric acid and pure water is performed to obtain an anode electrode.

Next, Nafion (trademark) 115 having a thickness of 127 μm as an electrolyte membrane 3 is interposed between the anode electrode 1 and the cathode electrode 2 manufactured as described above. Then, the anode electrode 1, the cathode electrode 2, and the electrolyte membrane 3 interposed therebetween are hot-pressed at 150° C. and 1 ton for three minutes, thereby manufacturing the electrochemical cell 10 which is a membrane/electrode assembly used in Example 1.

Each of the electrochemical apparatuses 20 of Examples 1 to 6 was operated by applying a voltage between electrodes of the electrochemical cell 10, in other words, between the anode electrode 1 and the cathode electrode 2, by a power supply 6. Consequently, water electrolysis is caused to generate oxygen from the anode electrode 1 and hydrogen from the cathode electrode 2. At that time, the current density is 2 A/cm², and the operation temperature is 80 degrees.

Cases where a cell voltage is less than 1.95 V, less than 2 V, and 2 V or greater are denoted by A, B, and C, respectively. A continuous operation is performed at 2 A/cm², thereby evaluating lifetime. At that time, a time point when a voltage exceeds 2.2 V is regarded as lifetime, and a cause of catalyst degradation can be examined by using cyclic voltammetry after the evaluation. When a reduction rate of a double layer capacitance after the degradation calculated from a cyclic voltammogram obtained by scanning from 1.2 to 0.2 V vs RHE is less than 50% in comparison to the initial stage, it means not degradation of the catalyst layer, but degradation of the intermediate layer. On the other hand, when the reduction rate is greater than or equal to 50%, it means degradation of the catalyst layer.

Evaluation results are also indicated in Table 1 above. Examples 1 to 6 exhibit excellent properties for both initial properties and durability under respective conditions.

As a target used in the vicinity of the substrate, Ta exhibits good results as well. The reason therefor is as follows. Since Ta has a heat conduction coefficient similar to that of Ti as the substrate, Ta exhibits high durability as with the case of Pt.

### Comparative Examples 1 to 8

An electrochemical apparatus 20 is prepared which uses the same catalyst layer of the anode as that used in Example 1, and an intermediate layer of which configuration has been changed from that used in Example 1. In Comparative Example 1, an intermediate layer having a thickness as large as 1000 nm is used, and in Comparative Example 2, an intermediate layer having a thickness as small as 2.5 nm is used. In Comparative Examples 3 and 4, respective intermediate layers include a single compound. The intermediate layer of Comparative Example 3 includes Pt only, and the intermediate layer of Comparative Example 4 includes IrO₂ only. Comparative Example 5 has been prepared by omitting the intermediate layer of the electrode of Example 1. In Comparative Example 6, the catalyst layer is a single layer which means a DSE type, and an intermediate layer is not inserted.

Contrary to the case of Example 1, Comparative Example 7 has been prepared such that a larger amount of IrO₂ is included in the substrate side, and a larger amount of Pt is included in the catalyst layer side. Comparative Example 8 is prepared as follows with reference to Japanese Patent No. 3743472. After dissolving 2 ml of titanium-n-butoxide in 200 ml of benzene, which is an aromatic compound solvent, a water/alcohol mixed solution including 0.106 ml of water and 2.48 ml of n-butanol is added dropwise under stirring at 6° C. Subsequently, hydrolysis and dehydration condensation are caused under ultrasonic waves at 6° C. for one hour. Thereafter, concentration is performed at 60° C. with an evaporator until a concentration as titanium ions reaches 0.6 mol/L, thereby preparing a polymer titanium dioxide solution. Then, the prepared polymer titanium dioxide solution is attached to a titanium substrate by a dipping method, and then dried at 200° C. for 20 minutes, thereby forming a thin film of titanium dioxide. As a catalyst layer provided thereon, the same IrO₂ laminate as that in Example 1 is used.

Results obtained from Comparative Examples 1 to 8 are indicated in Table 1. In Comparative Example 1, initial properties are found to be inferior to those in Examples. The reason for the deterioration of properties is presumed as follows. Since the intermediate layer has a thickness as large as 1000 nm, resistance in the intermediate layer increases, and thereby conductivity of electrons is inhibited.

The result obtained from Comparative Example 2 exhibits deterioration of durability in comparison to that obtained from Example 1. The reason for the decrease in durability is presumed as follows. The intermediate layer has an extremely small thickness of 2.5 nm. The small thickness affects distribution of Pt and IrO₂. Pt and IrO₂ are not uniformly rich in the vicinity of the substrate and the catalyst layer, respectively. Alternately, the small thickness causes direct contact between the catalyst layer and the substrate in some portions.

The results obtained from Comparative Examples 3 and 4 also exhibit deterioration of durability in comparison to that obtained from Example 1. In Comparative Example 3, since the intermediate layer includes Pt only, the intermediate layer and the catalyst layer have different thermal expansion coefficients from each other. Consequently, delamination occurred at an interface between the catalyst layer and the intermediate layer. In Comparative Example 4, since the intermediate layer includes IrO₂ only, the substrate and the intermediate layer have different thermal expansion coefficients from each other. Consequently, delamination occurs at an interface between the substrate and the intermediate layer.

Comparative Example 5 exhibits an evaluation result obtained in a case where the intermediate layer is not provided. In comparison to Example 1, durability is significantly decreased in Comparative Example 5, as well. Since heat conduction coefficients of the substrate and the catalyst layer are different from each other, delamination occurs at an interface between the substrate and the catalyst layer.

Comparative Example 6 exhibits a result obtained in a case of DSE. In comparison to Example 1, durability is improved, but initial properties are significantly deteriorated.

Comparative Example 7 exhibits a result obtained in a case where the intermediate layer has a configuration contrary to that in Example 1, in other words, IrO₂ and Pt are rich in the vicinity of the substrate and in the vicinity of the catalyst layer, respectively. Also in Comparative Example 7, durability is deteriorated for the difference in thermal expansion coefficients between the intermediate layer and respective interfaces.

Also in Comparative Example 8, durability was decreased as with other Comparative Examples.

Some elements are herein denoted only by element symbols thereof.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electrode comprising a substrate, an intermediate layer provided on the substrate, and a catalyst layer provided on the intermediate layer, wherein
the intermediate layer is a mixture that includes two or more substances among a compound, and single element of noble metal or an alloy including noble metal, and in a composition ratio of the mixture, a composition ratio of the intermediate layer in the vicinity of an interface between the substrate and the intermediate layer is different from a composition ratio of the intermediate layer in the vicinity of an interface between the catalyst layer and the intermediate layer.

2. The electrode according to claim 1, wherein the catalyst layer includes at least one substance among iridium oxide, ruthenium oxide, tantalum oxide, titanium oxide, platinum, and platinum oxide.

3. The electrode according to claim 1, wherein the mixture includes at least one substance in the group A and at least one substance in the group B below:
group A: iridium oxide, ruthenium oxide and gold;
group B: valve metal oxide, and platinum.

4. The electrode according to claim 3, wherein when an amount of a substance of the group B in the vicinity of the interface with the substrate is denoted by B1, and an amount of a substance of the group B in the vicinity of the interface with the catalyst layer is denoted by B2, the relationship B1>B2 is satisfied.

5. The electrode according to claim 3, wherein
the vicinity of the interface with the substrate is a region in the intermediate layer located within a thickness of 0.1×L, when L denotes a thickness of the intermediate layer, to the catalyst layer from the interface between the substrate and the intermediate layer, and
a composition ratio of a substance of the group A present in the vicinity of the interface with the substrate is greater than 0% and less than or equal to 10%.
present in, the region is meant by the vicinity of the interface with the substrate 1A,
a region in the intermediate layer 1C located within a thickness of 0.1×L (L denotes a thickness of the intermediate layer 1C) to the catalyst layer 1B from the interface between the substrate 1A and the intermediate layer 1C

6. The electrode according to claim 1, wherein a thickness of the intermediate layer is from 10 nm or more to 500 nm or less.

7. The electrode according to claim 1, wherein the catalyst layer has a laminated structure including an aggregate layer and a gap layer.

8. The electrode according to claim 7, wherein a thickness of the aggregate layer is from 4 nm or more to 30 nm or less.

9. The electrode according to claim 1, wherein a thermal expansion coefficient in the vicinity of the interface between the substrate and the intermediate layer is different from a thermal expansion coefficient in the vicinity of an interface between the catalyst layer and the intermediate layer.

10. An electrochemical cell that includes the electrode according to claim 1.

11. An electrochemical apparatus that includes the electrochemical cell according to claim 10.

12. A method for manufacturing an electrode that comprises a substrate, an intermediate layer provided on the substrate, and a catalyst layer provided on the intermediate layer, the method comprising:
forming the intermediate layer on the substrate by performing sputtering, the intermediate layer being a mixture that includes two or more substances among a compound, and single element of noble metal or an alloy including noble metal,
forming a mixed layer including a pore forming material and a catalyst material on the intermediate layer by performing the sputtering, and
dissolving the pore forming material from the mixed layer by using an acidic solution to obtain the catalyst layer.
